(19) United States
(12) Patent Application Publication
(10) Pub. No.: US 2025/0385175 A1
(43) Pub. Date: Dec. 18, 2025

(54) SEMICONDUCTOR INTERCONNECTION STRUCTURES AND MANUFACTURING METHOD THEREOF

(71) Applicant: Taiwan Semiconductor Manufacturing Company, Ltd., Hsinchu (TW)

(72) Inventors: Ching-Han Mao, Hsinchu (TW); Chih-Yi Chang, Taipei (TW); Wei-Yip LOH, Hsinchu (TW); Hung-Yi HUANG, Hsinchu (TW)

(73) Assignee: Taiwan Semiconductor Manufacturing Company, Ltd., Hsinchu (TW)

(21) Appl. No.: 18/746,647

(22) Filed: Jun. 18, 2024

(51) Int. Cl. H01L 23/522; H01L 21/768; H01L 23/532

(52) U.S. Cl. CPC H01L 23/5226; H01L 21/7682; H01L 21/76831; H01L 23/53266

(57) ABSTRACT

Provided are a semiconductor structure including: a first dielectric layer over a substrate; a conductive layer including a plurality of conductive layer sections located over the first dielectric layer; an isolating structure positioned between a first conductive layer section and a second conductive layer section of the plurality of conductive layer sections; wherein the isolating structure is bounded by a dielectric liner and includes a dielectric material layer disposed above an airgap between sidewalls of the dielectric liner; a first selective metal layer formed over the first conductive layer section, the first selective metal layer having a lower resistivity than a resistivity of the first conductive layer section; a second dielectric layer formed over the second conductive layer section and the isolating structure and on a sidewall of the first selective metal layer; and an etch stop layer formed over the second dielectric layer and the first selective metal layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a portion of an example semiconductor device at one stage in an integrated circuit manufacturing process, in accordance with some embodiments.

FIG. 2 is a process flow chart depicting an example method of semiconductor fabrication that includes forming a conductive structure that includes a wide-metal section, in accordance with some embodiments.

FIGS. 3-20 are cross-sectional diagrams that illustrate a semiconductor structure at various stages of fabrication, in accordance with some embodiments.

### DETAILED DESCRIPTION

The following disclosure provides many different embodiments, or examples, for implementing different features. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

In certain embodiments herein, a “material layer” is a layer that includes at least 50 wt. % of the identified material, for example at least 60 wt. % of the identified material, or at least 75 wt. % of the identified material, or at least 90 wt. % of the identified material; and a layer that is a “material” includes at least 50 wt. % of the identified material, for example at least 60 wt. % of the identified material, at least 75 wt. % of the identified material, or at least 90 wt. % of the identified material. For example, certain embodiments, each of a titanium nitride layer and a layer that is titanium nitride is a layer that is at least 50 wt. %, at least 60 wt. %, at least 75 wt. %, titanium nitride, or at least 90 wt. % titanium nitride.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Embodiments described herein provide for forming conductive interconnects. In particular, embodiments described herein may provide for forming conductive interconnects using a metal such as ruthenium (Ru). For example, embodiments described herein provide for forming isolating structures in a conductive interconnect formed using Ru that does not experience low-k dielectric damage at an interface between a low-k dielectric and a metal conductor layer, which can lead to higher capacitance. Embodiments described herein can provide conductive interconnects with reduced or tunable resistance. Embodiments described herein can provide lower carrier scattering (which can lead to lower resistance) as compared to a metal conductor such as Copper (Cu). Embodiments described herein can provide lower resistance due to not having a barrier between a low K dielectric layer and a conductive metal layer. Embodiments described herein can provide lower resistance due to low electron scattering. Embodiments described herein can provide lower resistance due to selective metal growth of a selective metal on a conductive metal layer. Embodiments described herein can provide lower capacitance due to incorporation of an air gap in the separating structure. Embodiments described herein may be applicable to a variety of semiconductor devices such as fin field-effect transistor (FinFET), Gate-all-around field-effect transistor (GAA FET), and complementary field-effect transistor (CFET) devices.

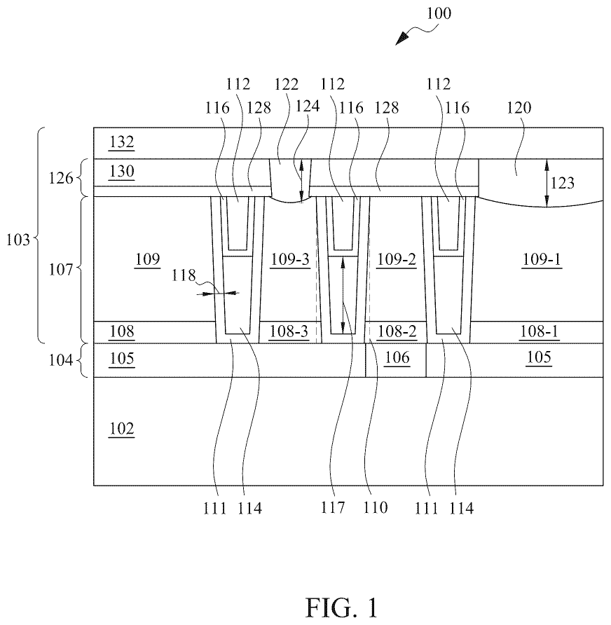

FIG. 1 is a cross-sectional view of a portion of an example semiconductor device 100 at one stage in an integrated circuit manufacturing process in accordance with an embodiment. Shown is a portion of a semiconductor device 100 having electrical circuitry formed in and/or upon a substrate 102 and a conductive structure 103 formed above the substrate. The substrate 102 may be one of a variety of types of semiconductor substrates commonly employed in semiconductor integrated circuit fabrication, and integrated circuits may be formed therein and/or thereupon. The semiconductor substrate may be of any construction comprising semiconductor materials, including but not limited to, bulk silicon, a semiconductor wafer, a silicon-on-insulator (SOI) substrate, or a silicon germanium substrate. Other semiconductor materials, including group III, group IV, and/or group V semiconductors, can be used. Although not shown, it will be recognized that the substrate 102 may further comprise a plurality of isolation features, such as shallow trench isolation (STI) features or local oxidation of silicon (LOCOS) features. The isolation features may isolate various microelectronic elements formed in and/or upon the substrate 102. Examples of the types of microelectronic elements that may be formed in the substrate 102 include, but are not limited to, transistors such as metal oxide semiconductor field effect transistors (MOSFETs), complementary metal oxide semiconductor (CMOS) transistors, bipolar junction transistors (BJTs), high voltage transistors, high frequency transistors, p-channel and/or n-channel field effect transistors (PFETs/NFETs), resistors, diodes, capacitors, inductors, fuses, and/or other suitable elements. Various processes are performed to form the various microelectronic elements, including but not limited to one or more of deposition, etching, implantation, photolithography, annealing, and other suitable processes. The microelectronic elements are interconnected to form the integrated circuit device, which may comprise one or more of a logic device, memory device (e.g., SRAM), radio frequency (RF) device, input/output (I/O) device, system-on-chip (SoC) device, and other suitable types of devices.

The example substrate 102 further includes a top layer 104. The top layer 104 may include various structures such as a dielectric layer 105 (e.g., an interlayer dielectric (ILD) layer) and one or more VIA connection points 106 for providing an electrical connection to microelectronic elements on or in the substrate 102.

The example conductive structure 103 comprises a conductive layer 107 disposed above the dielectric layer 105 that includes a titanium nitride (TiN) layer 108 and a metallic layer 109, and one or more isolating structures 110 configured to separate the conductive layer 107 into a plurality of conductive layer sections (e.g., a first conductive layer section comprising first metal layer section 109-1 and first TiN layer section 108-1, a second conductive layer section comprising second metal layer section 109-2 and second TiN layer section 108-2, and a third conductive layer section comprising third metal layer section 109-3 and third TiN layer section 108-3). In various embodiments, the metallic layer 109 is formed from ruthenium (Ru).

The example one or more isolating structures 110 are bounded by a dielectric liner 111 and comprises a dielectric material layer 112 disposed above an airgap 114 between sidewalls of the dielectric liner 111. The example one or more isolating structures 110 may include a sustain layer 116 disposed between the dielectric material layer 112 and the airgap 114. In various embodiments, the dielectric liner 111 is formed from a polymer such as silicon oxycarbide (SiOC), the dielectric material layer 112 is formed from a low-k dielectric, such as porous SiOC, and the sustain layer 116 is formed from SiO. In various embodiments, the dielectric constant (k value) of a low-k dielectric material can be less than about 3.9, or less than about 2.8. In various embodiments, the airgap has a height 117 of about 10 nanometers (nm) to about 20 nm. In various embodiments, the dielectric liner 111 has a thickness 118 of about 0.5 nm to about 3 nm.

The example conductive structure 103 further includes a first selective metal layer 120 formed over the first metal layer section 109-1 and a second selective metal layer 122 formed over the third metal layer section 109-3. The first selective metal layer 120 has a lower resistivity than a resistivity of the first metal layer section 109-1. The second selective metal layer 122 has a lower resistivity than a resistivity of the third metal layer section 109-3. The first metal layer section 109-1 is configured to provide a wide metal region such as a conductive line, a metal line, or a metal wire in the semiconductor device 100. The third metal layer section 109-3 is configured to provide a connection between an element in the substrate and a metal line in a conductive layer above the conductive structure 103.

The first selective metal layer 120 has a first metal height 123 that is selected to achieve a predetermined resistance range for a first hybrid metal section that comprises the first metal layer section 109-1 and the first selective metal layer 120. The first metal height 123 can be increased and the height of the first metal layer section 109-1 correspondingly decreased to achieve a desired resistance for the first hybrid metal section. In various embodiments, the first selective metal layer 120 has a first metal height 123 that is between about 5 nm and about 20 nm. The first metal layer section 109-1 and the first selective metal layer 120 combine to form the first hybrid metal section, which is configured to provide a tunable resistance for the first hybrid metal section that is tunable based on the heights of the first metal layer section 109-1 and the first selective metal layer 120. In various embodiments, the first selective metal layer 120 is formed from one or more of tungsten (W), molybdenum (Mo), cobalt (Co), Ruthenium (Ru), Rhodium (Rh), Iridium (Ir) or another suitable material. In various embodiments, the first selective metal layer 120 is formed from a metal with a λ*ρ₀<7×10⁻¹⁶ Ω*m², wherein ρ₀ is the resistivity of the metal and λ is the electron mean free path in the metal at room temperature. In various embodiments, the metal used in the first selective metal layer 120 can be selected to achieve a desirable resistance range. This can be useful for wide metal regions (e.g., metal lines) and SRAM areas that can suffer from RC performance loss when utilizing Ru as a metallic layer 109.

The second selective metal layer 122 has a second metal height 124 that is selected to achieve a predetermined resistance range for a second hybrid metal section that comprises the third metal layer section 109-3 and the second selective metal layer 122. In various embodiments, the second selective metal layer 122 has a second metal height 124 that is between about 0 nm and about 5 nm less than the first metal height 123. The third metal layer section 109-3 and the second selective metal layer 122 combine to form the first hybrid metal section, which is configured to provide a tunable resistance for the second hybrid metal section that is tunable based on the heights of the third metal layer section 109-3 and the second selective metal layer 122. In various embodiments, the second selective metal layer 122 is formed from one or more of tungsten (W), molybdenum (Mo), cobalt (Co), Ruthenium (Ru), Rhodium (Rh), Iridium (Ir) or another suitable material. In various embodiments, the second selective metal layer 122 is formed from the same metal material as the first selective metal layer 120. In various embodiments, second selective metal layer 122 is formed from a metal with a λ*ρ₀<7×10⁻¹⁶ Ω*m², wherein ρ₀ is the resistivity of the metal and λ is the electron mean free path in the metal at room temperature. In various embodiments, the metal used in the second selective metal layer 122 can be selected to achieve a desirable resistance range. The second selective metal layer 122 is configured as a VIA between the third metal layer section 109-3 and a subsequently formed upper conductive layer above the conductive structure 103.

The example conductive structure 103 further includes a second dielectric layer 126 comprising a dielectric liner layer 128 and a dielectric material layer 130 formed over portions of the metallic layer 109 including the second metal layer section 109-2, formed over the one or more isolating structures 110, formed on a sidewall of the first selective metal layer 120, and formed on a sidewall of the second selective metal layer 122. The example conductive structure 103 also includes an etch stop layer 132 formed over the dielectric layer and the first selective metal layer.

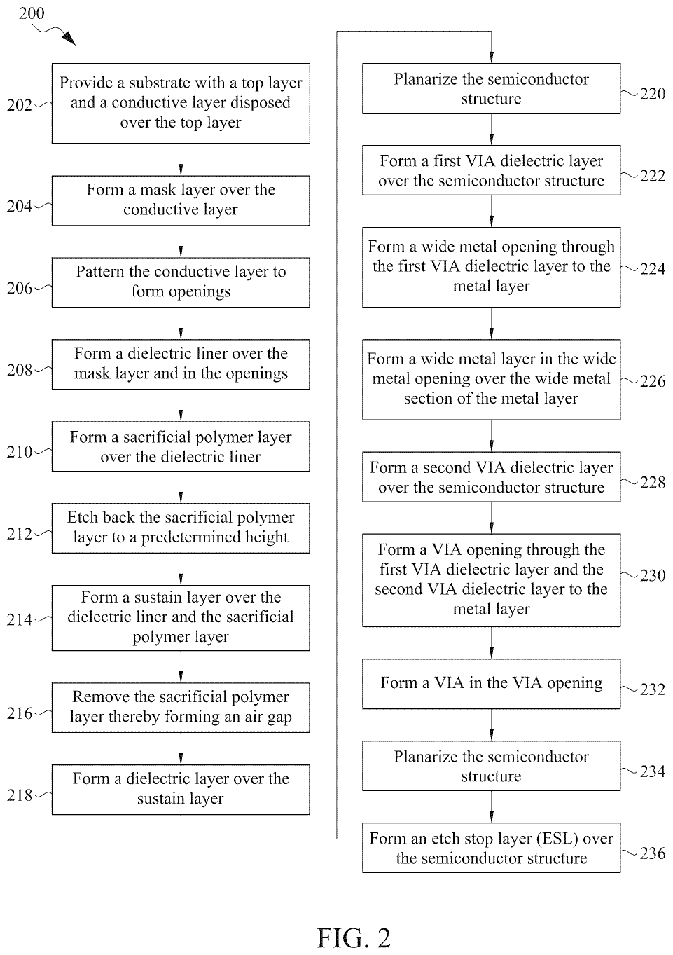

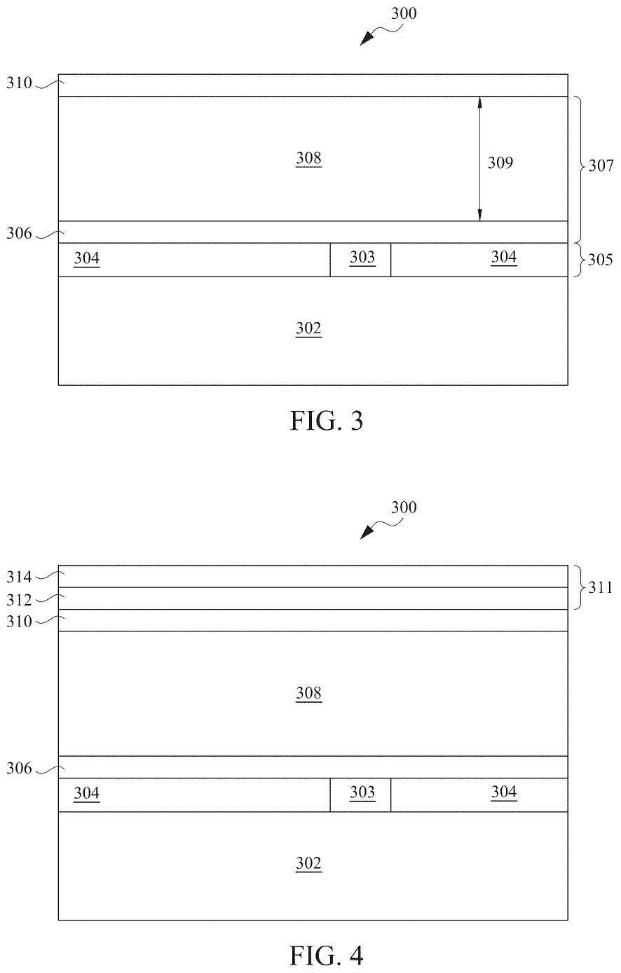

FIG. 2 is a process flow chart depicting an example method 200 of semiconductor fabrication that includes forming a conductive structure (e.g., conductive structure 103) that includes a wide-metal section (e.g., first metal layer section 109-1). FIG. 2 is described in conjunction with FIGS. 3-20, which illustrate a semiconductor structure 300 at various stages of fabrication in accordance with some embodiments. The method 200 is merely an example and is not intended to limit the present disclosure beyond what is explicitly recited in the claims. Additional steps may be provided before, during, and after method 200, and some of the steps described can be moved, replaced, or eliminated for additional embodiments of method 200. Additional features may be added in the semiconductor structure 300 depicted in the figures, and some of the features described below can be replaced, modified, or eliminated in other embodiments

As with the other method embodiments and exemplary devices discussed herein, it is understood that parts of the semiconductor structures may be fabricated by typical semiconductor technology process flow, and thus some processes are only briefly described herein. Further, the exemplary semiconductor structures may include various other devices and features, such as other types of devices such as additional transistors, bipolar junction transistors, resistors, capacitors, inductors, dials, fuses, and/or other logic devices, etc., but is simplified for better understanding of concepts of the present disclosure.

At block 202, the example method 200 includes providing a substrate with an interlayer dielectric (ILD) layer and one or more VIAs disposed in a top layer of the substrate, a first TiN layer disposed above the top layer, a conductive layer disposed above the first TiN layer, and a second TIN layer disposed above the conductive layer. Referring to the example of FIG. 3, in an embodiment of block 202, a substrate 302 with an ILD layer 304 and one or more VIAs 303 disposed in a top layer 305 of the substrate and a conductive layer 307 disposed above the top layer 305, wherein the conductive layer 307 comprises a first TiN layer 306 disposed above the top layer 305, a metal layer 308 disposed above the first TiN layer 306, and a second TiN layer 310 disposed above the metal layer 308. In various embodiments, the metal layer 308 comprises a transition metal. In various embodiments, the transition metal comprises Ruthenium (Ru). In various embodiments, the metal layer 308 has a height 309 of about 15 nm to about 40 nm.

At block 204, the example method 200 includes forming a mask layer over the conductive layer. In various embodiments, the mask layer is disposed over the second TiN layer. Referring to the example of FIG. 4, in an embodiment of block 204, a mask layer 311 is formed over the second TIN layer. In various embodiments, the mask layer 311 includes a plurality of sublayers. In various embodiments, the plurality of layers of the mask layer 311 includes a SiN layer 312 and a SiO layer 314. The mask layer may be formed by any suitable method, such as chemical vapor deposition (CVD), physical vapor deposition (PVD), or the like.

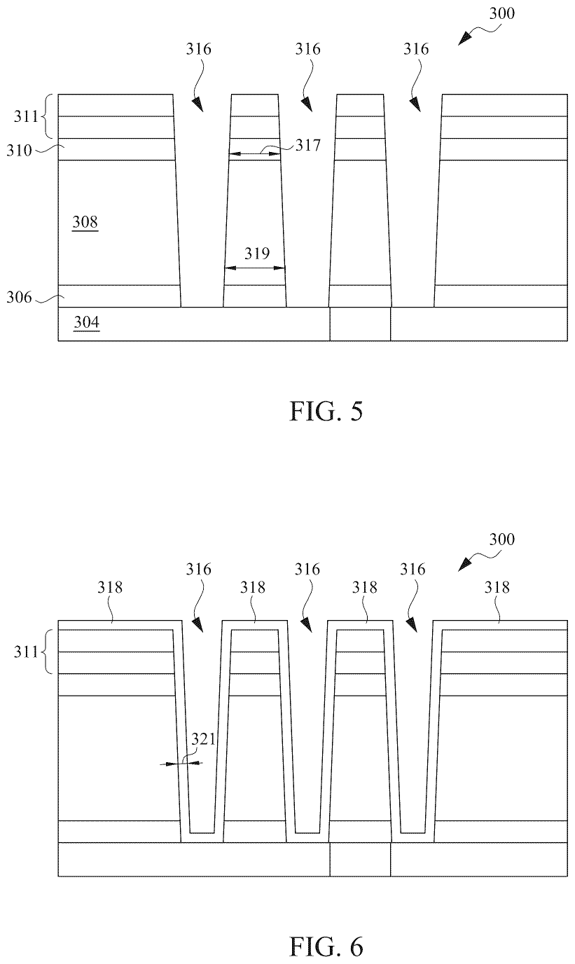

At block 206, the example method 200 includes patterning the conductive layer to form openings. Patterning the conductive layer includes forming openings that separate the conductive layer into various conductive sections. Forming openings can involve using reactive ion etching (RIE) techniques on the conductive layer. Referring to the example of FIG. 5, in an embodiment of block 206, the conductive layer 307 is patterned to form patterned sections of the conductive layer 307. The patterned sections of the conductive layer 307 are separated by openings 316 formed by patterning and etching the mask layer 311, the second TiN layer 310, metal layer 308, and the first TIN layer 306, and landing on the ILD layer 304. The etching may be performed by a suitable etching technique such as RIE. In various embodiments, the openings 316 are wider at the top, narrower at the bottom, and slope inwardly from top to bottom. In various embodiments, the patterned sections of the conductive layer 307 are narrower at the top, wider at the bottom, and have sidewalls that slope outwardly from top to bottom. The patterned sections of the conductive layer 307 may be used for VIA sections and wide metal sections. The VIA sections are used to support VIAs to higher metal layers and the wide metal sections are used to provide metal lines or wires in the semiconductor structure. In various embodiments, the VIA sections have an upper width 317 of about 6 nm to about 10 nm and a lower width 319 of about 8 nm to about 12 nm.

At block 208, the example method 200 includes forming a dielectric liner over the mask layer and in the openings. Referring to the example of FIG. 6, in an embodiment of block 208, a dielectric liner 318 is formed over the mask layer 311 and in the openings 316. In various embodiments, the dielectric liner 318 is formed from a polymer-derived ceramic such as silicon oxycarbide (SiOC). In various embodiments, the dielectric liner 318 has a thickness 321 of about 0.5 nm to about 3 nm.

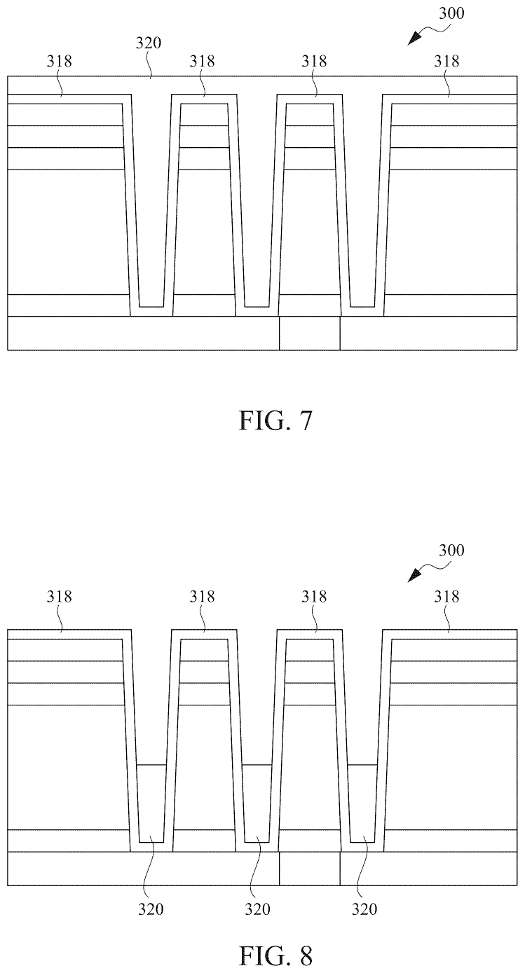

At block 210, the example method 200 includes forming a sacrificial polymer layer over the dielectric liner. Referring to the example of FIG. 7, in an embodiment of block 210, a sacrificial polymer layer 320 is formed over the dielectric liner 318. In various embodiments, the sacrificial polymer layer 320 is formed from ashless carbon (ALC). The sacrificial polymer layer 320 may be formed by any suitable method, such as chemical vapor deposition (CVD), physical vapor deposition (PVD), or the like.

At block 212, the example method 200 includes etching back the sacrificial polymer layer to a predetermined height. The predetermined height sets a subsequently formed air gap height. Referring to the example of FIG. 8, in an embodiment of block 212, the sacrificial polymer layer 320 has been etched back to a predetermined height in the openings 316.

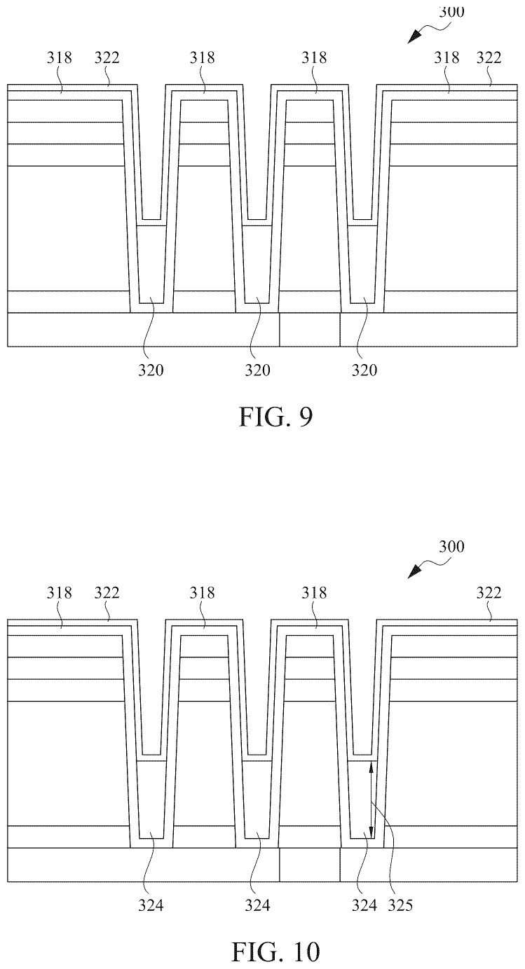

At block 214, the example method 200 includes forming a sustain layer over the dielectric liner and the sacrificial polymer layer. Referring to the example of FIG. 9, in an embodiment of block 214, a sustain layer 322 is formed over the dielectric liner 318 and the sacrificial polymer layer 320. In various embodiments, the sustain layer 322 is formed from a dielectric material such as SiOₓ. The sustain layer 322 may be formed by any suitable deposition method, such as chemical vapor deposition (CVD), physical vapor deposition (PVD), or the like. In various embodiments, the sacrificial polymer layer 320 has a concave top surface after etching back, and the sustain layer 322 has a rounded bottom surface.

At block 216, the example method 200 includes removing the sacrificial polymer layer thereby forming an air gap. In various embodiments, removing the sacrificial polymer layer 320 comprises performing ashing operations wherein the sacrificial polymer layer 320 is burned off. Referring to the example of FIG. 10, in an embodiment of block 216, an airgap 324 is formed in the openings 316 between the sustain layer 322 and the dielectric liner 318. In various embodiments, the airgap 324 has a height 325 of about 10 nm to about 20 nm. In some embodiments, not all of the sacrificial polymer layer 320 is burned off and a small portion of the sacrificial polymer layer 320 may remain in the airgap 324.

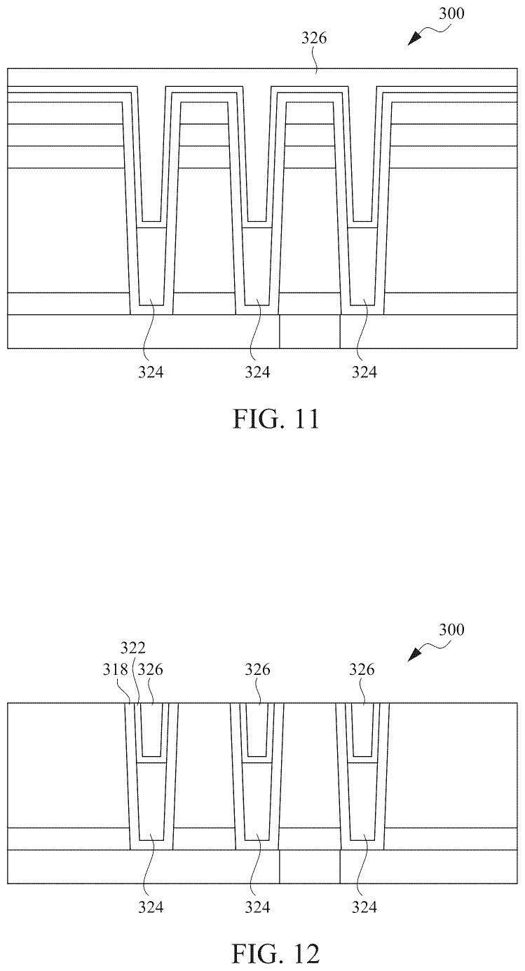

At block 218, the example method 200 includes forming a dielectric layer over the sustain layer. Referring to the example of FIG. 11, in an embodiment of block 218, a dielectric layer 326 is formed over the sustain layer 322. In various embodiments, the dielectric layer 326 is formed from a low k oxide such as Porous SiOC. The dielectric layer 326 may be formed by any suitable deposition method, such as chemical vapor deposition (CVD), physical vapor deposition (PVD), or the like.

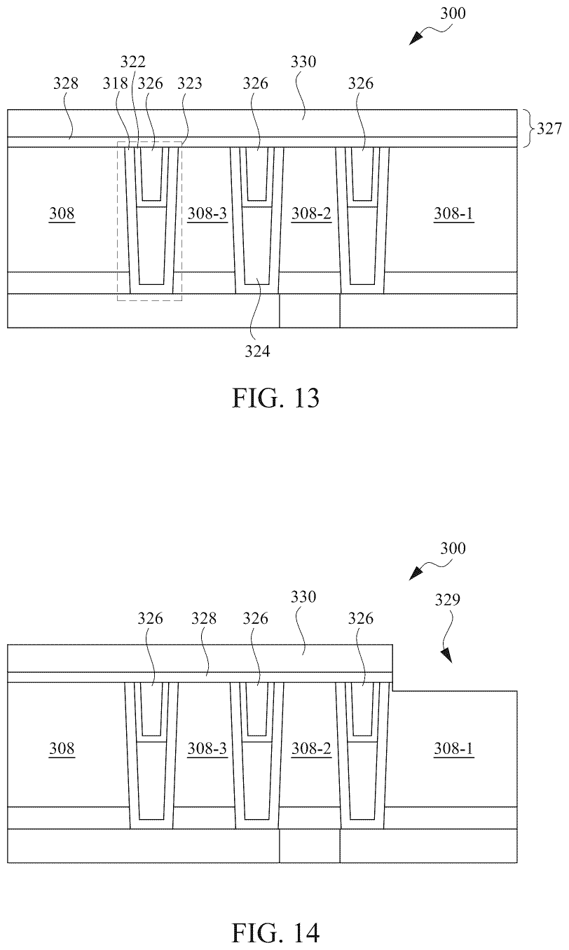

In various embodiments, the completion of block 206 through block 218 results in the formation of oner or more isolating structures 323 as identified in FIG. 13 (see also, isolating structures 110) that separate the metal layer 308 into a plurality of metal layer sections-first metal layer section 308-1, second metal layer section 308-2, and third metal layer section 308-3.

At block 220, the example method 200 includes planarizing the semiconductor structure. In various embodiments, planarizing the structure involves removing a top level of the dielectric layer 326, sustain layer 322, and dielectric liner 318, plus the mask layer 311 and second TiN layer 310. In various embodiments, planarizing the semiconductor structure includes performing chemical mechanical polishing (CMP) operations on the semiconductor structure. Referring to the example of FIG. 12, in an embodiment of block 220, the semiconductor structure 300 has been planarized to remove a top level of the dielectric layer 326, sustain layer 322, and dielectric liner 318, plus the mask layer 311 and second TiN layer 310. The various sections of the conductive layer 307 remain. The various sections of the conductive layer 307 are separated by dielectric liner 318, an airgap 324, the sustain layer 322, and the dielectric layer 326.

At block 222, the example method 200 includes forming a first VIA dielectric layer over the semiconductor structure. In various embodiments, the first VIA dielectric layer comprises a SIN layer and a low K dielectric material layer. Referring to the example of FIG. 13, in an embodiment of block 222, a first VIA dielectric layer 327 comprising a SiN layer 328 and a low K dielectric material layer 330 is formed over the semiconductor structure 300. The SiN layer 328 is formed over the semiconductor structure 300 and the low K dielectric material layer 330 is formed over the SiN layer 328. In various embodiments, the low K dielectric material layer 330 is formed from a low k oxide such as porous SiOC. The low K dielectric material layer 330 may be formed by any suitable deposition method, such as chemical vapor deposition (CVD), physical vapor deposition (PVD), or the like. The SiN layer 328 may be formed by any suitable deposition method, such as chemical vapor deposition (CVD), physical vapor deposition (PVD), or the like.

At block 224, the example method 200 includes forming a wide metal opening through the first VIA dielectric layer to the metal layer. In various embodiments, forming a wide metal opening involves lithography operations to define the location of the wide metal opening and etching operations to etch the wide metal opening. The etching operations to etch the wide metal opening may include reactive ion etching (RIE) operations. Referring to the example of FIG. 14, in an embodiment of block 224 a wide metal opening 329 is formed through the first VIA dielectric layer to the metal layer 308.

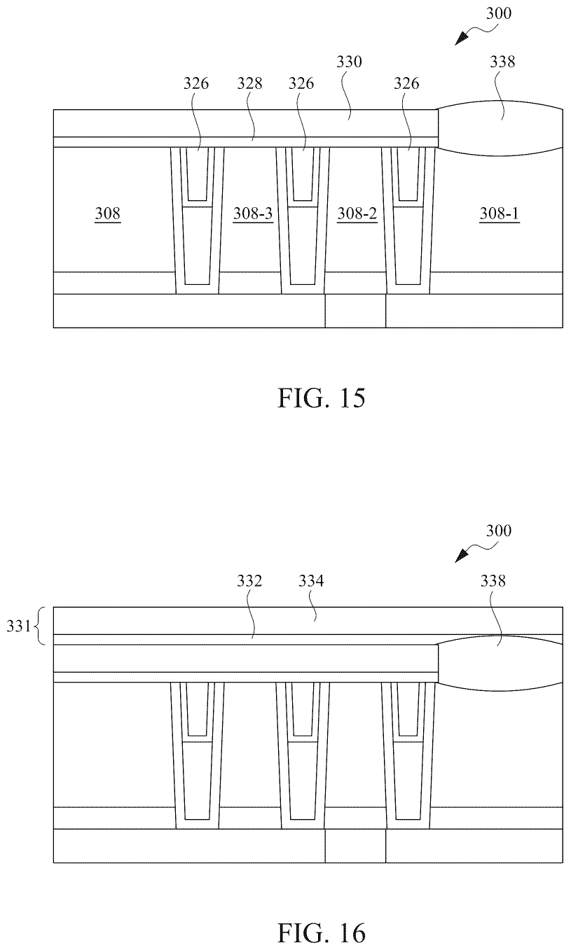

At block 226, the example method 200 includes forming a wide metal layer in the wide metal opening over the wide metal section of the metal layer. In various embodiments, forming the wide metal layer includes selective growth operations, such as selective atomic layer deposition or selective chemical vapor deposition. Referring to the example of FIG. 15, in an embodiment of block 226, a wide metal layer 338 has been formed in the wide metal opening 329. The wide metal layer 338 is configured to provide a low resistance electrical connection between the wide metal section of the metal layer 308 and a subsequently formed conductive segment in a higher layer.

The wide metal layer 338 may be formed from one or more of tungsten (W), molybdenum (Mo), cobalt (Co), Ruthenium (Ru), Rhodium (Rh), Iridium (Ir) or another suitable material. The wide metal layer 338 may be formed from a metal with λ*ρ₀<7×10⁻¹⁶ Ω*m².

At block 228, the example method 200 includes forming a second VIA dielectric layer over the semiconductor structure. In various embodiments, the second VIA dielectric layer comprises a SiN layer and a low K dielectric layer. Referring to the example of FIG. 16, in an embodiment of block 228, a second VIA dielectric layer 331 comprising a SiN layer 332 and a dielectric layer 334 is formed over the semiconductor structure 300. The SiN layer 332 is formed over the semiconductor structure 300 and a dielectric layer 334 is formed over the SiN layer 332. In various embodiments, the dielectric layer 334 is formed from a low k oxide such as porous SiO. The dielectric layer 334 may be formed by any suitable deposition method, such as chemical vapor deposition (CVD), physical vapor deposition (PVD), or the like. The SiN layer 332 may be formed by any suitable deposition method, such as chemical vapor deposition (CVD), physical vapor deposition (PVD), or the like.

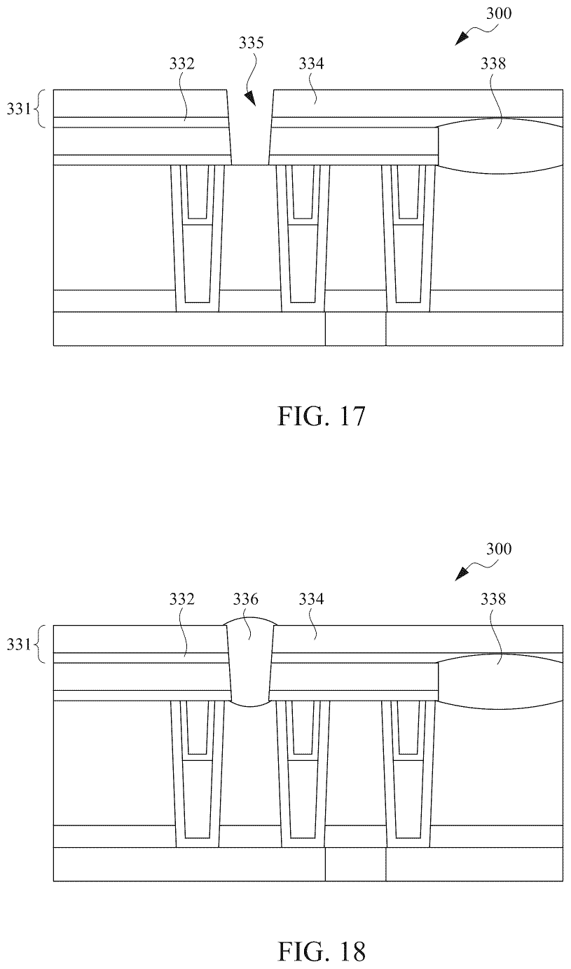

At block 230, the example method 200 includes forming a VIA opening through the first VIA dielectric layer and the second VIA dielectric layer to the metal layer. In various embodiments, forming a VIA opening involves lithography operations to define the location of the opening and etching operations to etch the opening. Referring to the example of FIG. 17, in an embodiment of block 230 a VIA opening 335 has been formed in the first VIA dielectric layer 327 and the second VIA dielectric layer 331.

At block 232, the example method 200 includes forming a VIA in the VIA opening. In various embodiments, forming the VIA includes selective growth operations, such as selective atomic layer deposition or selective chemical vapor deposition. Referring to the example of FIG. 18, in an embodiment of block 232, a VIA 336 has been formed in the VIA opening 335. The VIA 336 is configured to provide a low resistance electrical connection between conductive segments in two or more levels and/or layers of the semiconductor structure 300. The VIA 336 may be formed from one or more of copper (Cu), silver (Ag), tungsten (W), titanium (Ti), nickel (Ni), tin (Sn), aluminum (Al) or another metal or material suitable for providing low resistance electrical connections between semiconductor structure layers. In some embodiments, the bottom of the VIA 336 may partially cover (i.e., be in contact with) top surfaces of one or more of the dielectric liner 318, the sustain layer 322, and/or the dielectric layer 326.

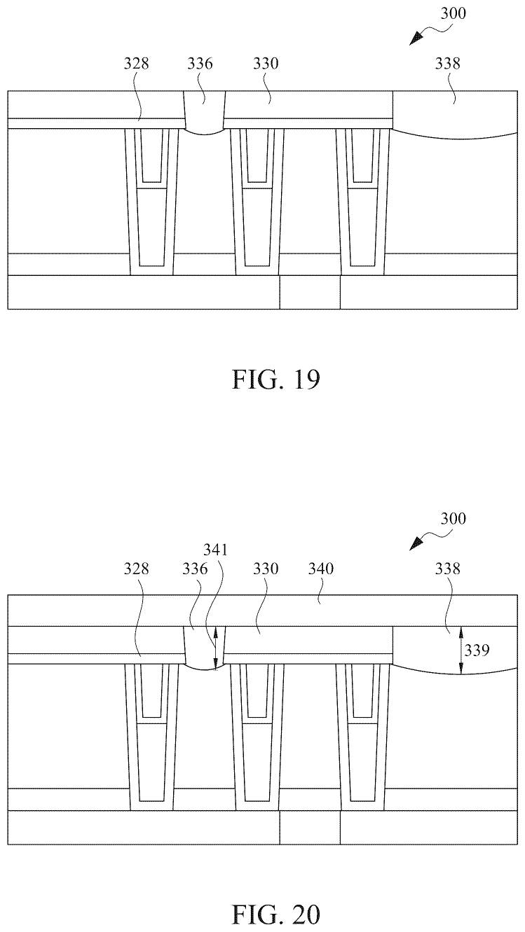

At block 234, the example method 200 includes planarizing the semiconductor structure. In various embodiments, planarizing the semiconductor structure involves performing CMP operations to planarize the VIA 336, the first VIA dielectric layer 327, and the wide metal layer 338 to a selected height. Referring to the example of FIG. 19, in an embodiment of block 234, the VIA 336, the first VIA dielectric layer 327, and the wide metal layer 338 have been planarized to a selected height. In various embodiments, the VIA 336 has a wider top portion and a narrower bottom portion wherein sidewalls of the VIA 336 slope inwardly. In various embodiments, the metal layer 308 directly under the VIA 336 has a narrower top portion and a wider bottom portion, wherein sidewalls of the metal layer 308 slope outwardly from top to bottom. In some embodiments, the bottom of the wide metal layer 338 may partially cover (i.e., be in contact with) top surfaces of one or more of the dielectric liner 318, the sustain layer 322, and/or the dielectric layer 326.

At block 236, the example method 200 includes forming an etch stop layer (ESL) over the semiconductor structure. Referring to the example of FIG. 20, in an embodiment of block 236, an ESL 340 has been formed over the VIA 336, the first VIA dielectric layer 327, and the wide metal layer 338. In various embodiments, the wide metal layer 338 has a height 339 of about 5 nm to about 20 nm. In various embodiments, the VIA 336 has a height 341 that is about 0 nm to about 5 nm lower than the height 339.

In various embodiments, a hybrid height (e.g., first metal height 123 plus height of first metal layer section 109-1) provides for RC tunability. This can be helpful for logic and SRAM devices. In various embodiments, use of a second selective metal layer (e.g., second selective metal layer 122) can ease gap fill issues with forming VIAs. In various embodiments, use of Ru RIE for the metallic layer (e.g., metallic layer 109) can provide for lower bulk resistance, prevent low-k damage, and be suitable for barrier-less integration. Various embodiments described herein are applicable to FinFET, GAA FET and CFET applications.

In some aspects, the techniques described herein relate to a method including: providing a semiconductor structure with an interlayer dielectric (ILD) layer and one or more VIAs disposed in a top layer of a substrate, a first dielectric (e.g., first TiN) layer disposed above the top layer, a conductive layer disposed above the first dielectric (e.g., first TiN) layer, and a second dielectric (e.g., second TiN) layer disposed above the conductive layer; forming an isolating structure that separates the conductive layer into a plurality of conductive layer sections including a first conductive layer section and a second conductive layer section, wherein the isolating structure includes a dielectric layer disposed above an airgap; forming a first VIA dielectric layer over the semiconductor structure; forming a first metal opening through the first VIA dielectric layer to a metal layer in the first conductive layer section; forming a first selective metal layer in the first metal opening.

In some aspects, the techniques described herein relate to a method, further including forming a second VIA dielectric layer over the semiconductor structure; planarizing the semiconductor structure; and forming an etch stop layer (ESL) over the semiconductor structure.

In some aspects, the techniques described herein relate to a method, wherein the conductive layer is formed from ruthenium (Ru).

In some aspects, the techniques described herein relate to a method, wherein forming the isolating structure includes: forming an isolating structure opening in the conductive layer; forming a dielectric liner over the second dielectric layer and in the isolating structure opening; forming a sacrificial polymer layer over the dielectric liner; etching back the sacrificial polymer layer; forming a sustain layer over the dielectric liner and the sacrificial polymer layer; removing the sacrificial polymer layer thereby forming an air gap; and forming a dielectric layer over the sustain layer.

In some aspects, the techniques described herein relate to a method, wherein the first selective metal layer and the first conductive layer section form a first hybrid metal section that is configured to provide a tunable resistance for the first hybrid metal section that is tunable based on heights of the first selective metal layer and the first conductive layer section.

In some aspects, the techniques described herein relate to a method, wherein the first selective metal layer and the first conductive layer section form a first hybrid metal section that is configured to provide a tunable resistance for the first hybrid metal section that is tunable based on metal material used in the first selective metal layer.

In some aspects, the techniques described herein relate to a method, wherein the first selective metal layer has a metal height that is between 5 nm and 20 nm.

In some aspects, the techniques described herein relate to a method, wherein the first conductive layer section is configured to form a metal conductive line for the semiconductor structure.

In some aspects, the techniques described herein relate to a method, wherein the first selective metal layer is formed from one or more of tungsten (W), molybdenum (Mo), cobalt (Co), Ruthenium (Ru), Rhodium (Rh), or Iridium (Ir).

In some aspects, the techniques described herein relate to a method, wherein the first selective metal layer is formed from a metal with λ*ρ₀<7×10⁻¹⁶ Ω*m².

In some aspects, the techniques described herein relate to a method, wherein the plurality of conductive layer sections includes a third conductive layer section and further including: forming a VIA opening through the first VIA dielectric layer, through the second VIA dielectric layer, and in the third conductive layer section; and forming a second selective metal layer in the VIA opening over the third conductive layer section, wherein the second selective metal layer is configured as a VIA between the third conductive layer section and a subsequently formed upper conductive layer.

In some aspects, the techniques described herein relate to a method, wherein the second selective metal layer has a metal height that is between 0 nm and 5 nm less than a height of the first selective metal layer.

In some aspects, the techniques described herein relate to a method, wherein the second selective metal layer has a metal height that is selected to achieve a predetermined resistance range for a second hybrid metal section including the second selective metal layer and the third conductive layer section.

In some aspects, the techniques described herein relate to a method, wherein the second selective metal layer is formed from a metal material that is used to form the first selective metal layer.

In some aspects, the techniques described herein relate to a method, wherein the second selective metal layer and the first conductive layer section form a second hybrid metal section that is configured to provide a tunable resistance for the second hybrid metal section that is tunable based on metal material used in the second selective metal layer.

In some aspects, the techniques described herein relate to a semiconductor structure including: a first dielectric layer over a substrate; a conductive layer including a plurality of conductive layer sections located over the first dielectric layer; an isolating structure positioned between a first conductive layer section and a second conductive layer section of the plurality of conductive layer sections; wherein the isolating structure is bounded by a dielectric liner and includes a dielectric material layer disposed above an airgap between sidewalls of the dielectric liner; a first selective metal layer formed over the first conductive layer section, the first selective metal layer having a lower resistivity than a resistivity of the first conductive layer section.

In some aspects, the techniques described herein relate to a semiconductor structure, further including a second dielectric layer formed over the second conductive layer section and the isolating structure and on a sidewall of the first selective metal layer and an etch stop layer (ESL) formed over the second dielectric layer and the first selective metal layer.

In some aspects, the techniques described herein relate to a semiconductor structure, wherein the conductive layer is formed from ruthenium (Ru).

In some aspects, the techniques described herein relate to a semiconductor structure, further including a sustain layer disposed between the dielectric material layer and the airgap.

In some aspects, the techniques described herein relate to a semiconductor structure, wherein the first selective metal layer has a metal height that is selected to achieve a predetermined resistance range for a first hybrid metal section including the first selective metal layer and the first conductive layer section.

In some aspects, the techniques described herein relate to a semiconductor structure, wherein the first selective metal layer has a metal height that is between 5 nm and 20 nm.

In some aspects, the techniques described herein relate to a semiconductor structure, wherein the first conductive layer section is configured to form a metal conductive line for the semiconductor structure.

In some aspects, the techniques described herein relate to a semiconductor structure, wherein the first selective metal layer and the first conductive layer section form a first hybrid metal section that is configured to provide a tunable resistance for the first hybrid metal section that is tunable based on metal material used in the first selective metal layer.

In some aspects, the techniques described herein relate to a semiconductor structure, wherein the first selective metal layer is formed from one or more of tungsten (W), molybdenum (Mo), cobalt (Co), Ruthenium (Ru), Rhodium (Rh), or Iridium (Ir).

In some aspects, the techniques described herein relate to a semiconductor structure,

wherein the first selective metal layer is formed from a metal with λ*ρ₀<7×10⁻¹⁶ Ω*m².

In some aspects, the techniques described herein relate to a semiconductor structure, further including: a third conductive layer section of the plurality of conductive layer sections; and a second selective metal layer formed over the third conductive layer section, below the ESL, and within an opening in the second dielectric layer, the second selective metal layer having a lower resistivity than a resistivity of the second conductive layer section; wherein the second selective metal layer is configured as a VIA between the third conductive layer section and a subsequently formed upper conductive layer.

In some aspects, the techniques described herein relate to a semiconductor structure, wherein the second selective metal layer has a metal height that is between 0 nm and 5 nm less than a height of the first selective metal layer.

In some aspects, the techniques described herein relate to a semiconductor structure, wherein the second selective metal layer has a metal height that is selected to achieve a predetermined resistance range for a second hybrid metal section including the second selective metal layer and the third conductive layer section.

In some aspects, the techniques described herein relate to a semiconductor structure, wherein the second selective metal layer is formed from a metal material that is used to form the first selective metal layer.

In some aspects, the techniques described herein relate to a semiconductor structure, wherein the second selective metal layer and the first conductive layer section form a second hybrid metal section that is configured to provide a tunable resistance for the second hybrid metal section that is tunable based on metal material used in the second selective metal layer.

In some aspects, the techniques described herein relate to a semiconductor structure, wherein the second selective metal layer is formed from one or more of tungsten (W), molybdenum (Mo), cobalt (Co), Ruthenium (Ru), Rhodium (Rh), or Iridium (Ir).

In some aspects, the techniques described herein relate to a semiconductor structure, wherein the second selective metal layer is formed from a metal with λ*ρ₀<7×10⁻¹⁶ Ω*m².

In some aspects, the techniques described herein relate to a method including: providing a semiconductor structure with a Ru (ruthenium) layer; forming an isolating structure that separates the Ru layer into a plurality of conductive layer sections including a first conductive layer section and a second conductive layer section, wherein the isolating structure includes a dielectric layer disposed above an airgap; forming a first VIA dielectric layer over the semiconductor structure; forming a first metal opening through the first VIA dielectric layer to the first conductive layer section; forming, in the first metal opening, a first selective metal layer that is selected to achieve a desired resistance for a first hybrid metal section including the first selective metal layer and the first conductive layer section; forming a second VIA dielectric layer over the semiconductor structure; planarizing the semiconductor structure; and forming an etch stop layer (ESL) over the semiconductor structure.

In some aspects, the techniques described herein relate to a method, wherein forming the isolating structure includes: forming an isolating structure opening in the Ru layer; forming a dielectric liner over the second TiN layer and in the isolating structure opening; forming a sacrificial polymer layer over the dielectric liner; etching back the sacrificial polymer layer to a predetermined height; forming a sustain layer over the dielectric liner and the sacrificial polymer layer; removing the sacrificial polymer layer thereby forming an air gap; and forming a dielectric layer over the sustain layer.

In some aspects, the techniques described herein relate to a method, wherein the first selective metal layer and the first conductive layer section form a first hybrid metal section that is configured to provide a tunable resistance for the first hybrid metal section that is tunable based on heights of the first selective metal layer and the first conductive layer section.

In some aspects, the techniques described herein relate to a method, wherein the first selective metal layer and the first conductive layer section form a first hybrid metal section that is configured to provide a tunable resistance for the first hybrid metal section that is tunable based on metal material used in the first selective metal layer.

In some aspects, the techniques described herein relate to a method, wherein the first selective metal layer has a metal height that is between 5 nm and 20 nm.

In some aspects, the techniques described herein relate to a method, wherein the first conductive layer section is configured to form a metal conductive line for the semiconductor structure.

In some aspects, the techniques described herein relate to a method, wherein the first selective metal layer is formed from one or more of tungsten (W), molybdenum (Mo), cobalt (Co), Ruthenium (Ru), Rhodium (Rh), or Iridium (Ir).

In some aspects, the techniques described herein relate to a method, wherein the first selective metal layer is formed from a metal with λ*ρ₀<7×10⁻¹⁶ Ω*m².

In some aspects, the techniques described herein relate to a method, wherein the Ru layer includes a third conductive layer section and further including: forming a VIA opening through the first VIA dielectric layer, through the second VIA dielectric layer, and in the third conductive layer section; and forming a second selective metal layer in the VIA opening over the third conductive layer section, wherein the second selective metal layer is configured as a VIA between the third conductive layer section and a subsequently formed upper conductive layer.

In some aspects, the techniques described herein relate to a method, wherein the second selective metal layer has a metal height that is between 0 nm and 5 nm less than a height of the first selective metal layer.

In some aspects, the techniques described herein relate to a method, wherein the second selective metal layer has a metal height that is selected to achieve a predetermined resistance range for a second hybrid metal section including the second selective metal layer and the third conductive layer section.

In some aspects, the techniques described herein relate to a method, wherein the second selective metal layer is formed from a metal material that is used to form the first selective metal layer.

In some aspects, the techniques described herein relate to a method, wherein the second selective metal layer and the first conductive layer section form a second hybrid metal section that is configured to provide a tunable resistance for the second hybrid metal section that is tunable based on metal material used in the second selective metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A method comprising:
providing a semiconductor structure with an interlayer dielectric (ILD) layer and one or more VIAs disposed in a top layer of a substrate, a first dielectric layer disposed above the top layer, a conductive layer disposed above the first dielectric layer, and a second dielectric layer disposed above the conductive layer;
forming an isolating structure that separates the conductive layer into a plurality of conductive layer sections including a first conductive layer section and a second conductive layer section, wherein the isolating structure includes a dielectric layer disposed above an airgap;
forming a first VIA dielectric layer over the semiconductor structure;
forming a first metal opening through the first VIA dielectric layer to a metal layer in the first conductive layer section; and
forming a first selective metal layer in the first metal opening.

2. The method of claim 1, wherein forming the isolating structure comprises:
forming an isolating structure opening in the conductive layer;
forming a dielectric liner over the second dielectric layer and in the isolating structure opening;
forming a sacrificial polymer layer over the dielectric liner;
etching back the sacrificial polymer layer;
forming a sustain layer over the dielectric liner and the sacrificial polymer layer;
removing the sacrificial polymer layer thereby forming an air gap; and
forming a dielectric layer over the sustain layer.

3. The method of claim 1, wherein the first selective metal layer and the first conductive layer section form a first hybrid metal section that is configured to provide a tunable resistance for the first hybrid metal section that is tunable based on heights of the first selective metal layer and the first conductive layer section.

4. The method of claim 1, wherein the first selective metal layer and the first conductive layer section form a first hybrid metal section that is configured to provide a tunable resistance for the first hybrid metal section that is tunable based on metal material used in the first selective metal layer.

5. The method of claim 1, wherein the plurality of conductive layer sections includes a third conductive layer section and further comprising:
forming a VIA opening through the first VIA dielectric layer and in the third conductive layer section; and
forming a second selective metal layer in the VIA opening over the third conductive layer section, wherein the second selective metal layer is configured as a VIA between the third conductive layer section and a subsequently formed upper conductive layer.

6. The method of claim 1, further comprising:
forming a second VIA dielectric layer over the semiconductor structure;
planarizing the semiconductor structure; and
forming an etch stop layer (ESL) over the semiconductor structure.

7. A semiconductor structure comprising:
a first dielectric layer over a substrate;
a conductive layer comprising a plurality of conductive layer sections located over the first dielectric layer;
an isolating structure positioned between a first conductive layer section and a second conductive layer section of the plurality of conductive layer sections;
wherein the isolating structure is bounded by a dielectric liner and comprises a dielectric material layer disposed above an airgap between sidewalls of the dielectric liner; and
a first selective metal layer formed over the first conductive layer section, the first selective metal layer having a lower resistivity than a resistivity of the first conductive layer section.

8. The semiconductor structure of claim 7, further comprising:
a second dielectric layer formed over the second conductive layer section and the isolating structure and on a sidewall of the first selective metal layer; and
an etch stop layer (ESL) formed over the second dielectric layer and the first selective metal layer.

9. The semiconductor structure of claim 7, wherein the conductive layer is formed from ruthenium (Ru).

10. The semiconductor structure of claim 7, further comprising a sustain layer disposed between the dielectric material layer and the airgap.

11. The semiconductor structure of claim 7, wherein the first selective metal layer has a metal height that is selected to achieve a predetermined resistance range for a first hybrid metal section comprising the first selective metal layer and the first conductive layer section.

12. The semiconductor structure of claim 7, wherein the first selective metal layer has a metal height that is between 5 nm and 20 nm.

13. The semiconductor structure of claim 7, wherein the first selective metal layer and the first conductive layer section form a first hybrid metal section that is configured to provide a tunable resistance for the first hybrid metal section that is tunable based on metal material used in the first selective metal layer.

14. The semiconductor structure of claim 7, wherein the first selective metal layer is formed from tungsten (W), molybdenum (Mo), cobalt (Co), Ruthenium (Ru), Rhodium (Rh), Iridium (Ir), or a metal with a λ*ρ₀<7×10⁻¹⁶ Ω*m².

15. A method comprising:
providing a semiconductor structure with a Ru layer (ruthenium layer);
forming an isolating structure that separates the Ru layer into a plurality of conductive layer sections including a first conductive layer section and a second conductive layer section, wherein the isolating structure includes a dielectric layer disposed above an airgap;
forming a first VIA dielectric layer over the semiconductor structure;
forming a first metal opening through the first VIA dielectric layer to the first conductive layer section;
forming, in the first metal opening, a first selective metal layer that is selected to achieve a desired resistance for a first hybrid metal section comprising the first selective metal layer and the first conductive layer section;
forming a second VIA dielectric layer over the semiconductor structure;
planarizing the semiconductor structure; and
forming an etch stop layer (ESL) over the semiconductor structure.

16. The method of claim 15, wherein the Ru layer is disposed above a first TiN layer and a second TiN layer is disposed above the Ru layer.

17. The method of claim 15, wherein the Ru layer includes a third conductive layer section and further comprising:
forming a VIA opening through the first VIA dielectric layer, through the second VIA dielectric layer, and in the third conductive layer section; and
forming a second selective metal layer in the VIA opening over the third conductive layer section, wherein the second selective metal layer is configured as a VIA between the third conductive layer section and a subsequently formed upper conductive layer.

18. The method of claim 17, wherein the second selective metal layer has a metal height that is between 0 nm and 5 nm less than a height of the first selective metal layer.

19. The method of claim 17, wherein the second selective metal layer has a metal height that is selected to achieve a predetermined resistance range for a second hybrid metal section comprising the second selective metal layer and the third conductive layer section.

20. The method of claim 17, wherein the second selective metal layer and the first conductive layer section form a second hybrid metal section that is configured to provide a tunable resistance for the second hybrid metal section that is tunable based on metal material used in the second selective metal layer.
